(19) United States
(12) Patent Application Publication
(10) Pub. No.: US 2007/0042276 A1
(43) Pub. Date: Feb. 22, 2007

(54) Lithography apparatus and method for using the same

(75) Inventor: Sang Man Bae, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Icheon-si (KR)

(21) Appl. No.: 11/481,638

(22) Filed: Jul. 5, 2006

(30) Foreign Application Priority Data
Aug. 19, 2005 (KR) 10-2005-0076213

(51) Int. Cl. G03F 1/14; A47G 1/12; G03F 1/00

(52) U.S. Cl. 430/5; 428/14

(57) ABSTRACT

The lithography apparatus includes a dummy photomask comprising a substrate having a photomask pattern and a photomask. The photomask being detachable/attachable from the photomask is attached to a photomask so as to adjust field CD uniformity of the photomask.

### CROSS-REFERENCES TO RELATED APPLICATIONS

The present application claims priority to Korean patent application number 10-2005-0076213, filed on Aug. 19, 2005, which is incorporated by reference in its entirety.

### BACKGROUND OF THE INVENTION

The present invention relates to a lithography technology. More particularly, the present invention relates to a method for using a lithography apparatus having a detachable/attachable dummy photomask.

In general, a lithography process refers to a patterning process during the fabrication of a semiconductor device. That is, the lithography process is a series of processes wherein a photomask is first formed, and then a lithography light such as a LASER is passed through the photomask to project the photomask pattern onto the semiconductor wafer.

A photomask is created by forming a predetermined mask over a quartz substrate having a shield layer. During the forming of the photomask, when the projection uniformity of an E-beam is poor and the surface condition for the etched shield layer is bad, a CD difference in the photomask pattern occurs.

If a lithography process is performed on the wafer with the photomask having the CD difference, the CD difference over the wafer becomes magnified. Generally, such a result is referred to as Field or chip CD uniformity.

In addition, the field CD uniformity occurs due to the CD difference of the photomask pattern over the conventional photomask. However, even if the photomask pattern has a uniform CD, the light passing through many lenses as well as the photomask may reach the surface of the wafer with inconsistent energy distribution.

Such field CD uniformity makes a gradual difference of the pattern from the center of a chip to each of its corner during the conventional process for fabricating the semiconductor device, which results in degrading quality of the device.

In order to solve the above problem, many photomasks have repeatedly been formed. However, remaking the expensive photomask increases the process cost.

In another solution, a dummy pattern for adjusting the field CD uniformity of the photomask has been formed on the rear of the photomask to control the passing energy. However, it is very difficult to fabricate such a photomask. That is, if the rear dummy pattern is incorrectly made and contains defects, the photomask may be contaminated and the whole photomask is made useless.

In addition, it has to be checked how much the CD difference of the photomask influences the projection on the wafer or how the CD difference is formed on the wafer during the process for forming the photomask pattern before the dummy pattern is formed on the rear of the photomask. Thus, it is inconvenient to remove the photomask from the lithography apparatus in order to form the dummy pattern on the rear of the photomask.

### BRIEF SUMMARY OF THE INVENTION

The present invention relates to a method for using a lithography apparatus wherein a lithography process is performed using a photomask attached with a detachable/attachable dummy photomask. The photomask is capable of adjusting field CD uniformity of light passing through the photomask, thereby allowing a fine pattern to be projected over a semiconductor substrate.

According to an embodiment of the present invention, a lithography apparatus includes: a dummy photomask including a substrate having a photomask pattern and a photomask, wherein the photomask is attached with the attachable/detachable dummy photomask so as to adjust the field CD uniformity of the photomask.

According to another embodiment of the present invention, a lithography method includes: (a) forming a photoresist film pattern over a semiconductor substrate by an exposure and development process using a photomask, (b) comparing the photoresist film pattern with a photomask pattern in the photomask to determine field CD difference of the photomask, and (c) performing a lithography process using the photomask attached with a dummy photomask to compensate for the field CD difference in the photomask.

In one embodiment of the present invention, the detachable/attachable dummy photomask, separated from the photomask by a predetermined distance, is disposed on the rear of the photomask. The dummy photomask is attached to the photomask by the same method as used for attaching pellicle on the front of the photomask. In addition, the dummy photomask includes a quartz substrate with a thickness less than half of that of the quartz substrate in the photomask.

In another embodiment, the size of the dummy photomask is equal to or less than that of the photomask so that the dummy photomask is disposed where field CD uniformity of the photomask needs to be compensated. In addition, the photomask pattern of the dummy photomask is selected from a shield pattern, a phase shift mask (PSM) pattern, or combination thereof. The photomask pattern of the dummy photomask is bar-shaped or hole-shaped.

Further, density of the photomask pattern of the dummy photomask gradually increases from one side of the dummy photomask to the other side in a horizontal direction and in a vertical direction. Density of the photomask pattern of the dummy photomask gradually increases from the center of the dummy photomask to the boundary in a horizontal direction and in a vertical direction. Density of the photomask pattern of the dummy photomask gradually increases from each corner of the dummy photomask to the center. Density of the photomask pattern of the dummy photomask gradually increases from center of the dummy photomask to each corner.

In another embodiment, a dummy photomask includes a first substrate that is configured to be attached or detached to a second substrate of a photomask. A photomask pattern is provided on the first substrate. Density of the photomask pattern of the dummy photomask gradually increases from a first point on the first substrate to a second point on the first substrate.

### BRIEF DESCRIPTION OF THE DRAWINGS

FIG. 1 is a simplified cross-sectional view illustrating a lithography apparatus according to the present invention.

FIG. 2 is a simplified top view illustrating a lithography apparatus according to a first embodiment of the present invention.

FIG. 3 is a simplified cross-sectional view illustrating a lithography apparatus according to the first embodiment of the present invention.

FIG. 4 is a simplified top view illustrating a lithography apparatus according to a second embodiment of the present invention.

FIG. 5 is a simplified cross-sectional view illustrating a lithography apparatus according to the second embodiment of the present invention.

FIG. 6 is a simplified top view illustrating a lithography apparatus according to a third embodiment of the present invention.

FIG. 7 is a simplified cross-sectional view illustrating a lithography apparatus according to the third embodiment of the present invention.

FIG. 8 is a simplified top view illustrating a lithography apparatus according to a fourth embodiment of the present invention.

FIG. 9 is a simplified top view illustrating a lithography apparatus according to a fifth embodiment of the present invention.

FIG. 10 is a simplified top view illustrating a lithography apparatus according to a sixth embodiment of the present invention.

FIG. 11 is a simplified top view illustrating a lithography apparatus according to a seventh embodiment of the present invention.

FIG. 12 is a simplified top view illustrating a lithography apparatus according to an eighth embodiment of the present invention.

FIG. 13 is a simplified top view illustrating a lithography apparatus according to a ninth embodiment of the present invention.

FIG. 14 is a simplified top view illustrating a lithography apparatus according to a tenth embodiment of the present invention.

### DESCRIPTION OF SPECIFIC EMBODIMENTS

The present invention relates to a method for using a lithography apparatus wherein a lithography process is performed using a photomask attached with a detachable/attachable dummy photomask. The photomask is capable of adjusting field CD uniformity of light passing through, thereby allowing a fine pattern to be projected over a semiconductor substrate.

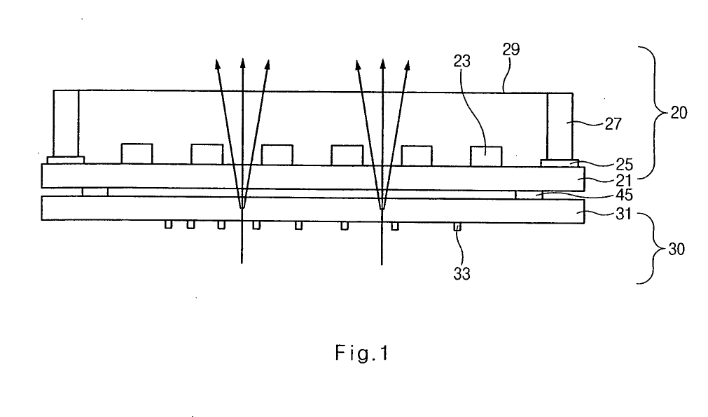

Referring to FIG. 1, a photomask 20 is attached with a dummy photomask 30 for adjusting field CD uniformity, such as energy distribution of light during a lithography process. Here, the photomask 20 includes a photomask pattern 23 over a substrate 21 and a pellicle 29 for preventing the photomask pattern 23 from being contaminated. The photomask 20 includes pellicle holding members 25 disposed at the edge of the substrate 21, pellicle holding frames 27 disposed over the pellicle holding members 25 for separating the pellicle from the photomask pattern 23 by a predetermined distance, and the pellicle 29 disposed over the pellicle holding frames 27. In addition, the substrate 21 of the photomask 20 is formed of quartz with its thickness ranging from about 70 mil to 250 mil.

In one embodiment of the present invention, a dummy photomask 30 is detachable/attachable from the photomask 20, and the dummy photomask 30 is disposed on the rear of the photomask 20 with a dummy photomask holding member 45. Here, the dummy photomask 30 includes a substrate 31 having a photomask pattern 33. The substrate 31 of the dummy photomask 30 is formed of quartz with its thickness being less than half of that of the substrate 21 of the photomask 20. That is, the thickness of the substrate 31 of the dummy photomask 30 ranges from about 5 mil to 40 mil. In addition, the dummy photomask 30 is separated from the photomask 20 by a predetermined thickness being less than about 2 mil. The dummy photomask 30 can be attached on the rear of the photomask 20 by using the same method for attaching the pellicle 29 on the front of the photomask 20.

In another embodiment, the photomask pattern 33 of the dummy photomask 30, which is bar-shaped or hole-shaped, is selected from a shield pattern, a phase shift mask (PSM) pattern, or combination thereof. Here, the shield photomask pattern 33 of the dummy photomask 30 is formed of chrome over a quartz substrate with a transparency of 100%. The PSM photomask pattern 33 of the dummy photomask 30 is formed of a phase shift material with a transparency of about 4˜10% or by etching a predetermined thickness of the quartz substrate with a transparency of about 90˜100%. In addition, the size of the dummy photomask 30 is equal to or less than that of the photomask 20. Thus, a plurality of dummy photomasks 30 can be attached on the rear of the photomask 20 where the field CD uniformity of the photomask 20 needs to be adjusted.

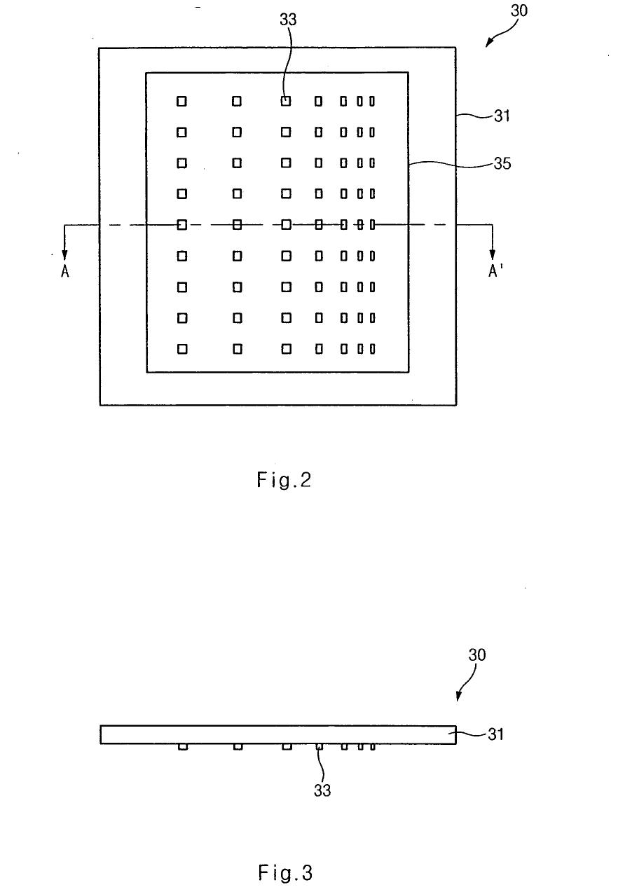

FIG. 2 is a simplified top view illustrating a lithography apparatus according to a first embodiment of the present invention, and FIG. 3 is a simplified cross-sectional view taken along the line A-A′ of FIG. 2.

Referring to FIGS. 2 and 3, a shield photomask pattern 33 is formed with a plurality of bar patterns disposed over a substrate 31 of a chip region 35 in a dummy photomask 30. Density of the photomask pattern 33 of the dummy photomask 30 gradually increases from one side of the dummy photomask 30 to the other side in a horizontal direction. In particular, the density of the photomask pattern 33 increases from the left side of the dummy photomask 30 to the right side.

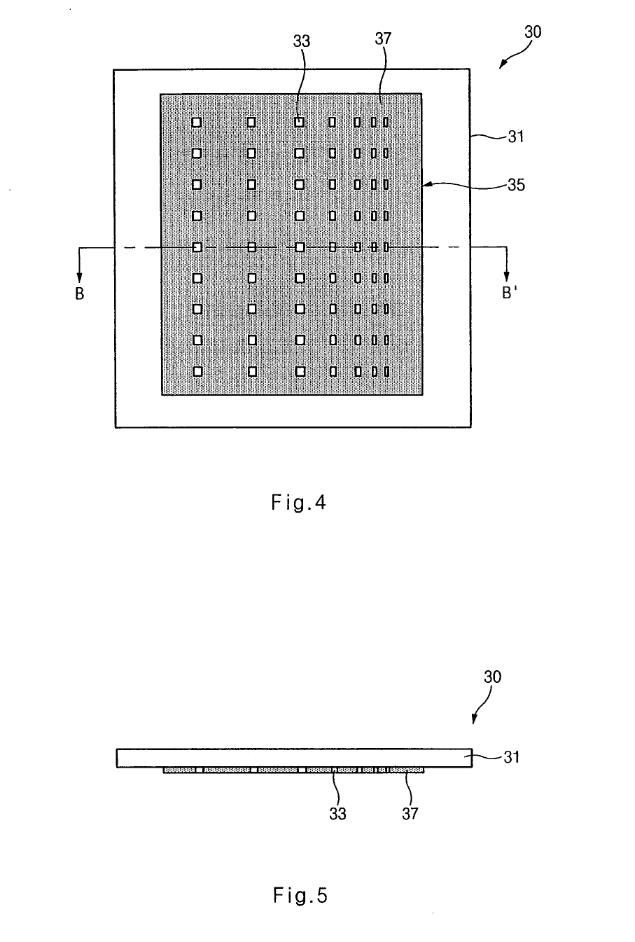

FIG. 4 is a simplified top view illustrating a lithography apparatus according to a second embodiment of the present invention, and FIG. 5 is a simplified cross-sectional view taken along the line B-B′ of FIG. 4.

Referring to FIGS. 4 and 5, a shield film 37 is formed over a substrate 31 of a chip region 35 in the dummy photomask 30. A plurality of holes is formed in the shield film 37 to form the dummy photomask pattern 33.

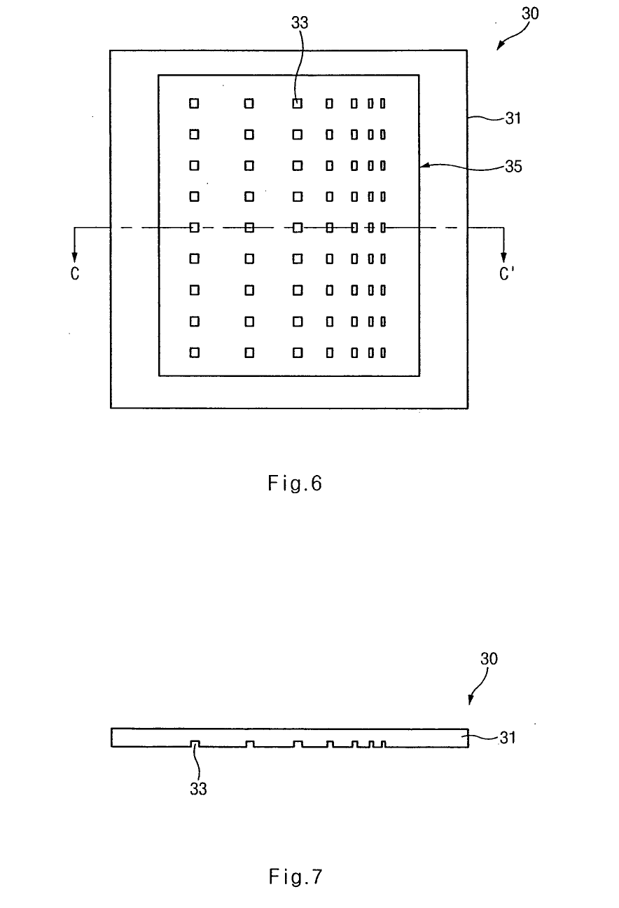

FIG. 6 is a simplified top view illustrating a lithography apparatus according to a third embodiment of the present invention, and FIG. 7 is a simplified cross-sectional view taken along the line C-C′ of FIG. 6.

Referring to FIGS. 6 and 7, the photomask pattern 33 is formed in a dummy photomask 30 by etching a predetermined thickness of a substrate 31 of a chip region 35. Here, the substrate 31 is formed of quartz with a transparency of about 90-100%.

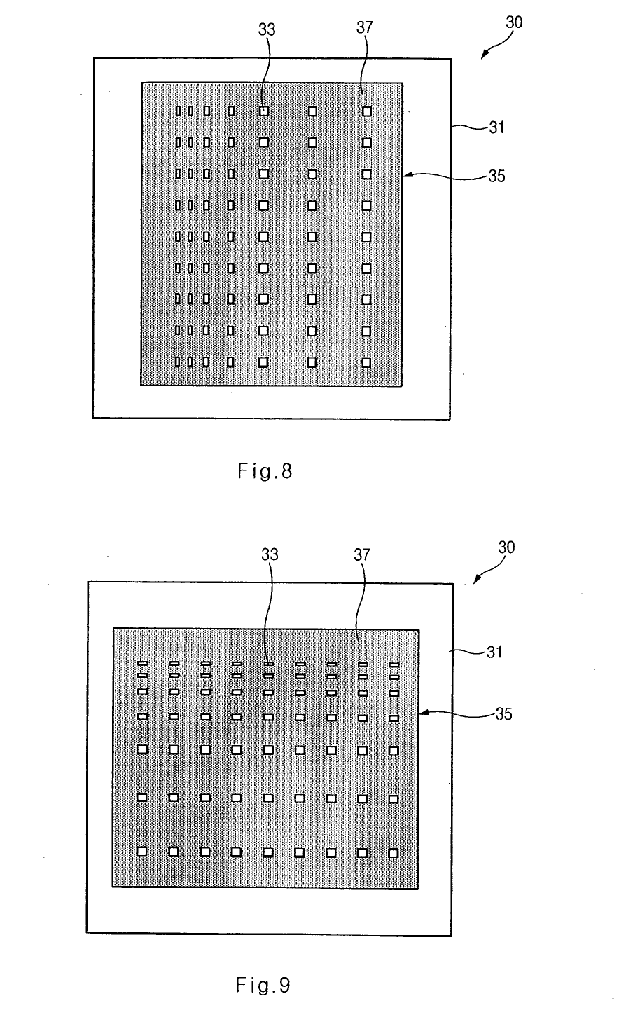

Respectively, FIGS. 8 through 12 are simplified top views according to fourth, fifth, sixth, seventh, eighth, and ninth embodiments of the present invention, wherein photomask patterns 33 of a dummy photomask 30 are formed with a plurality of holes with different density.

Referring to FIG. 8, density of the photomask pattern 33 gradually increases from the right side of the dummy photomask 30 to the left side.

Referring to FIG. 9, density of the photomask pattern 33 gradually increases from the near side of the dummy photomask 30 to the far side.

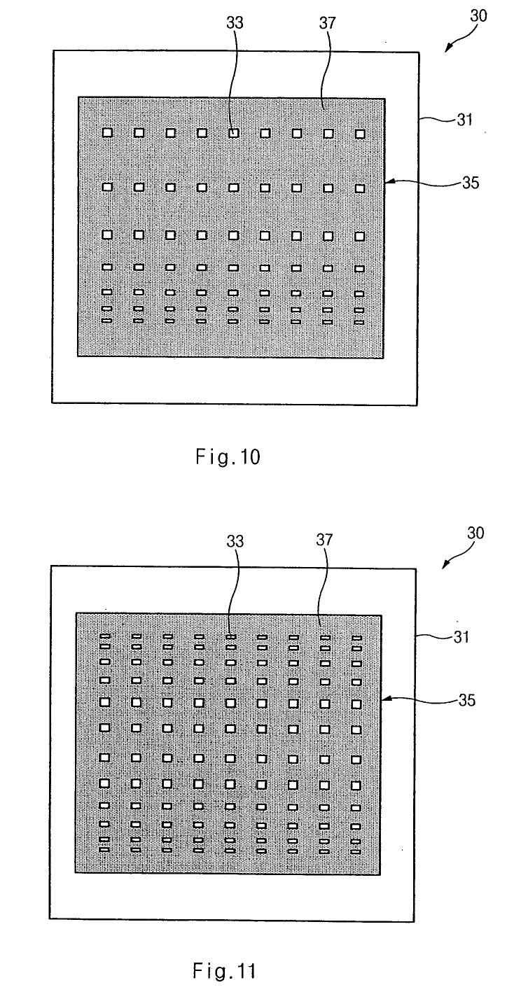

Referring to FIG. 10, density of the photomask pattern 33 gradually increases from the far side of the dummy photomask 30 to the near side.

Referring to FIG. 11, density of the photomask pattern 33 gradually increases from the horizontal center line of the dummy photomask 30 to the boundary in a vertical direction.

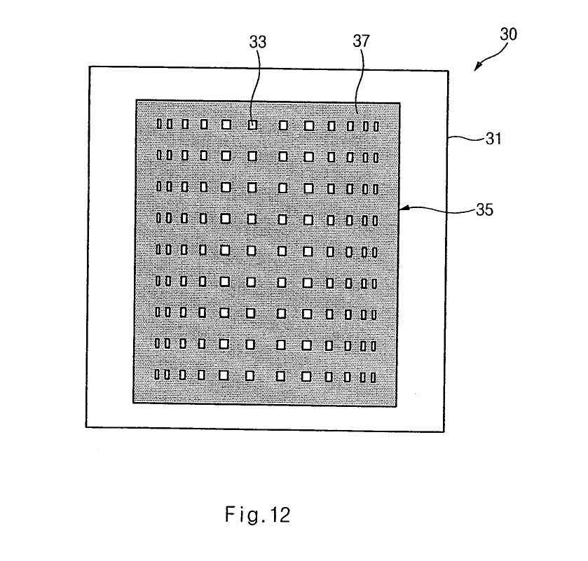

Referring to FIG. 12, density of the photomask pattern 33 gradually increases from the vertical center line of the dummy photomask 30 to the boundary in a horizontal direction.

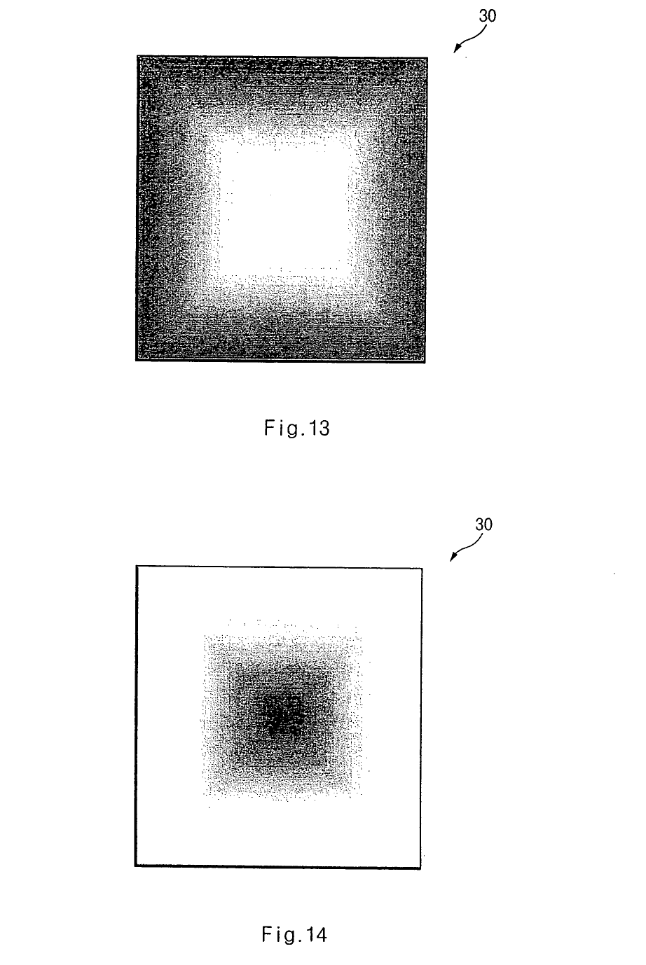

FIGS. 13 and 14 are simplified top views illustrating a lithography apparatus according to ninth and tenth embodiments of the present invention, respectively. Particularly, FIGS. 13 and 14 simply shows the density of the photomask pattern of a dummy photomask 30 so as to compensate for distorted energy distribution from the center of the photomask to its each corner.

Referring to FIG. 13, the density of the photomask pattern gradually increases from the center of the dummy photomask 30 to each corner.

Referring to FIG. 14, the density of the photomask pattern gradually increases from each corner of the dummy photomask 30 to the center.

The following is a lithography process (not shown) according to one embodiment of the present invention. First, a photomask having a photomask pattern is loaded into a lithography apparatus. A photoresist film pattern is formed over a semiconductor substrate having a photoresist film by an exposure and development process using the photomask. Second, field CD uniformity of the light passing through the photomask is determined by comparing the photoresist film pattern and the photomask pattern of the photomask. Finally, a dummy photomask according to one embodiment of the present invention is attached to the photomask to compensate the determined field CD uniformity in the subsequent lithography process. In one embodiment of the present invention the dummy photomask, separated from the photomask with a predetermined distance, is attached on the rear of the photomask. In addition, the dummy photomask is detachable/attachable from the photomask for reuse. That is, after the used dummy photomask is detached from the photomask and cleaned, the dummy photomask can be attached on another photomask.

Accordingly, the lithography method according to the present invention can adjust the field CD uniformity of the light passing through the photomask, thereby easily allowing a fine pattern to be projected over the semiconductor substrate.

Accordingly, the process for fabricating a semiconductor device can be simplified, and the productivity and yield of the device can be improved.

The foregoing description of various embodiments of the invention has been presented for purposes of illustration and description. It is not intended to be exhaustive or to limit the invention to the precise form disclosed, and modifications and variations are possible in light of the above teachings or acquired from practice of the invention. The embodiments were chosen and described in order to explain the principles of the invention and its practical application to enable one skilled in the art to utilize the invention in various embodiments and with various modifications as are suited to the particular use contemplated.

What is claimed is:

1. A lithography apparatus comprising:
a dummy photomask including a first substrate having a photomask pattern, the dummy photomask being configured to be attached or detached to a photomask; and
a photomask having a second substrate,
wherein the photomask is attached to the dummy photomask so as to adjust field CD uniformity of the photomask.

2. The lithography apparatus according to claim 1, wherein a thickness of the first substrate of the dummy photomask is no more than one half of that of the second substrate of the photomask, wherein the first and second substrates are quartz substrates.

3. The lithography apparatus according to claim 1, wherein the photomask pattern of the dummy photomask is bar-shaped or hole-shaped.

4. The lithography apparatus according to claim 1, wherein density of the photomask pattern of the dummy photomask gradually increases from one side of the dummy photomask to the other side in a first direction.

5. The lithography apparatus according to claim 4, wherein density of the photomask pattern of the dummy photomask gradually increases from a first point on the dummy photomask to a second point on the dummy photomask.

6. The lithography apparatus according to claim 1, wherein density of the photomask pattern of the dummy photomask gradually increases from a center of the dummy photomask to a boundary thereof in a first direction.

7. The lithography apparatus according to claim 6, wherein the first direction is a horizontal direction.

8. The lithography apparatus according to claim 1, wherein density of the photomask pattern of the dummy photomask gradually increases from a center of the dummy photomask to each corner thereof.

9. The lithography apparatus according to claim 1, wherein density of the photomask pattern of the dummy photomask gradually increases from each corner of the dummy photomask to center thereof.

10. The lithography apparatus according to claim 1, wherein the photomask pattern of the dummy photomask is one selected from a shield pattern, a phase shift mask (PSM) pattern, and a combination thereof.

11. The lithography apparatus according to claim 1, wherein a size of the dummy photomask is equal to or less than that of the photomask so that the dummy photomask is disposed where field CD uniformity needs to be compensated.

12. A lithography method comprising:
forming a photoresist film pattern over a semiconductor substrate by an exposure and development process using a photomask;
comparing the photoresist film pattern with a photomask pattern of the photomask to determine Field CD difference of the photomask; and
performing a lithography process using the photomask attached with a dummy photomask to compensate the Field CD difference for the photomask, the dummy photomask being configured to be attached and detached to the photomask.

13. The lithography method according to claim 12, wherein the dummy photomask is spaced apart from the photomask by a predetermined distance from a backside of the photomask.

14. The lithography method according to claim 12, wherein the dummy photomask is attached on the backside of the photomask using the same as that used to attach a pellicle on a front side of the photomask.

15. The lithography method according to claim 12, wherein the dummy photomask includes a substrate having a photomask pattern.

16. The lithography method according to claim 15, wherein the substrate of the dummy photomask is formed of quartz with its thickness being less than a half of that of a substrate of the photomask.

17. The lithography method according to claim 15, wherein the photomask pattern in the dummy photomask is one selected from a shield pattern, a phase shift pattern, and a combination thereof.

18. The lithography method according to claim 12, wherein a size of the dummy photomask is equal to or less then that of the photomask so that the dummy photomask is disposed where the field CD uniformity of the photomask needs to be compensated.

19. A dummy photomask, comprising:
a first substrate that is configured to be attached or detached to a second substrate of a photomask; and
a photomask pattern provided on the first substrate.

20. The dummy photomask of claim 19, wherein density of the photomask pattern of the dummy photomask gradually increases from a first point on the first substrate to a second point on the first substrate.
